(19) United States
(12) Patent Application Publication
(10) Pub. No.: US 2012/0300954 A1
(43) Pub. Date: Nov. 29, 2012

(54) Noiseless Motor Apparatus and Denoise Driver

(76) Inventor: Chiung-Ching Ku, Hsinchu County (TW)

(21) Appl. No.: 13/208,319

(22) Filed: Aug. 11, 2011

(30) Foreign Application Priority Data
May 26, 2011 (TW) 100118426

(51) Int. Cl. H03B 29/00

(52) U.S. Cl. 381/71.1

(57) ABSTRACT

A motor apparatus includes a motor, a speaker for generating a denoise sound wave according to a speaker driving signal to offset a noise generated by the motor, and a driving device including a memory for storing a noise characteristic information of the motor, a control circuit for determining a rotation speed and a rotation angle of the motor to generate a rotation information and generating a noise simulation information according to the rotation information and the noise characteristic information, a motor driver for driving the motor according to the rotation information, and an active denoise circuit including a synthesizer for generating an inverted noise simulation signal according to the noise simulation information, and a speaker driver for generating the speaker driving signal according to the inverted noise simulation signal.

### BACKGROUND OF THE INVENTION

1. Field of the Invention

The present invention relates to a noiseless motor apparatus and denoise driving device, and more particularly, to a noiseless motor apparatus and denoise driving device for offsetting motor noise according to a pre-stored noise information.

2. Description of the Prior Art

As the electronic circuit technology evolves, the heat-dissipating requirement for electronic devices increases. In order to improve the heat-dissipating efficiency, a fan is generally installed inside an electronic devices, which means restraint for the noise produced by the fan becomes stricter. In addition to improve the structure of the motor to reduce air-borne sound of the motor, offsetting the noise of the motor through a speaker is also feasible to reduce the noise.

Please refer to FIG. 1, which is a schematic diagram of a conventional motor system 10. The motor system 10 includes a motor 100, a microphone 110, a speaker 120, a driving module 130 and a denoise module 140. The driving module 130 includes an input circuit 132, an amplify circuit 134 and a current driver 136. The input circuit 132 processes a pulse width modulation (PWM) signal VPWM and a motor position signal VRP detected by a Hall sensor to generate a control signal VCON. The amplify circuit 134 amplifies the control signal VCON to generate a driving signal VD. The current driver 136 generates a driving current ID according to the driving signal VD, so as to drive the motor 100. The microphone 110 collects a noise of the motor 100 to generate a noise signal VN. The denoise module 140 includes a signal amplifier 142, a low pass filter 144, an inverted sound wave generator 146 and an output driver 148. The signal amplifier 142 amplifies the noise signal VN recorded by the microphone 110 to generate an amplified noise signal VN′. The low pass filter 144 performs low-pass filtering one the amplified noise signal VN′ to obtain a sound wave signal VAU among a main noise frequency band. The inverted sound wave generator 146 generates an inverted sound wave signal VAU′ having a same amplitude and an inverse phase as the sound wave signal VAU. The output driver 148 drives the speaker 120 to output the inverted sound wave according to the inverted sound wave signal VAU′. As a result, the noise of the motor 100 can be offset by superposition of the sound waves.

However, since the microphone 110 ages as long working times and the microphone 110 may receive its own air-borne sound, which results in an extra noise, the recorded noise signal VN and the actual motor noise may be inconsistent. In such a situation, the inverted sound wave outputted by the speaker 120 cannot offset the motor noise, and may generates extra noise. Besides, the denoise module 140 needs to realize complicated functions of signal processing, which increases cost of the motor system 10.

Therefore, it has become an issue in the industry to offset motor noise with a low-cost and durable method.

### SUMMARY OF THE INVENTION

It is therefore an object of the present invention to provide a motor apparatus, a denoise driving device and a driving device.

The present invention discloses a motor apparatus, including a motor for rotating according to a motor driving signal, a speaker for generating a denoise sound wave according to a speaker driving signal to offset a noise of the motor, and a driving device includes a memory for storing a noise characteristic information of the motor, a control circuit for determining a rotation speed and a rotation angle of the motor to generate a rotation information and generate a noise simulation information according to the rotation information and the noise characteristic information, a motor driver for generating the motor driving signal according to the rotation information, and an active denoise circuit including a synthesizer for generating an inverted noise simulation signal according to the noise simulation information, and a speaker driver for generating the speaker driving signal according to the inverted noise simulation signal.

The present invention further discloses a denoise driving device for driving a motor and eliminating a noise of the motor, the denoise driving device includes a speaker for generating a denoise sound wave according to a speaker driving signal, to offset the noise of the motor, and a driving device including a memory for storing a noise characteristic information of the motor, a control circuit for determining a rotation speed and a rotation angle of the motor, to generate a rotation information, and generate a noise simulation information according to the rotation information and the noise characteristic information, a motor driver for generating a motor driving signal according to the rotation information, to drive the motor, and an active denoise circuit including a synthesizer for generating an inverted noise simulation signal according to the noise simulation information, and a speaker driver for generating the speaker driving signal according to the inverted noise simulation signal.

The present invention further discloses a driving device for driving a motor and a speaker, the speaker is used for generating a denoise sound wave according to a speaker driving signal, to offset a noise of the motor, the driving device includes a memory for storing a noise characteristic information of the motor, a control circuit for determining a rotation speed and a rotation angle of the motor, to generate a rotation information, and generate a noise simulation information according to the rotation information and the noise characteristic information, a motor driver for generating a motor driving signal according to the rotation information, to drive the motor, and an active denoise circuit including a synthesizer for generating an inverted noise signal according to the noise simulation information, and a speaker driver for generating the speaker driving signal according to the inverted noise signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a conventional motor system.

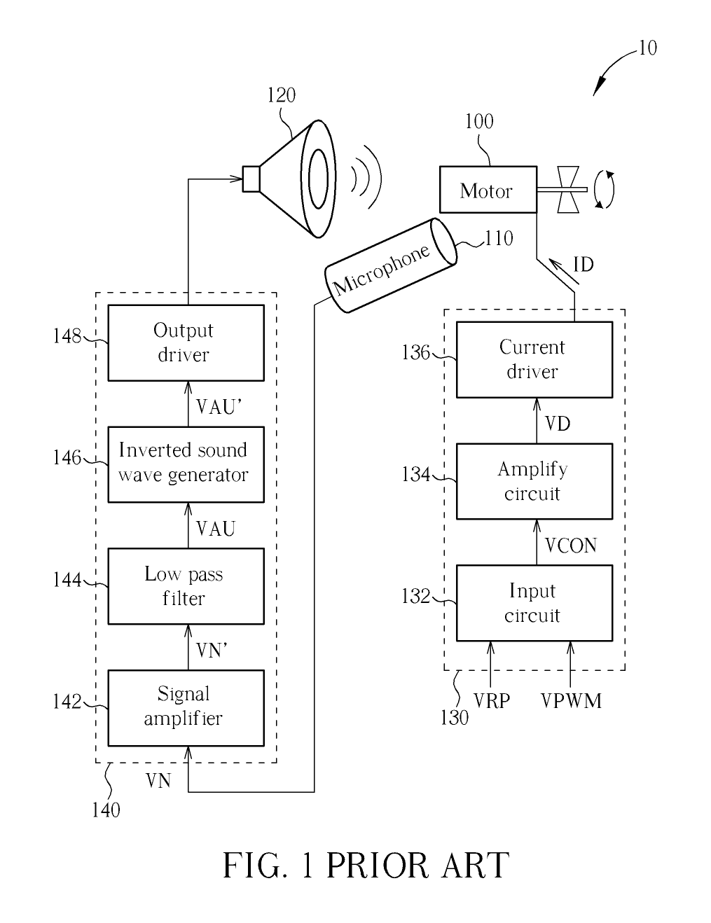

FIG. 2 is a schematic diagram of a motor apparatus according to the embodiment of the present invention.

### DETAILED DESCRIPTION

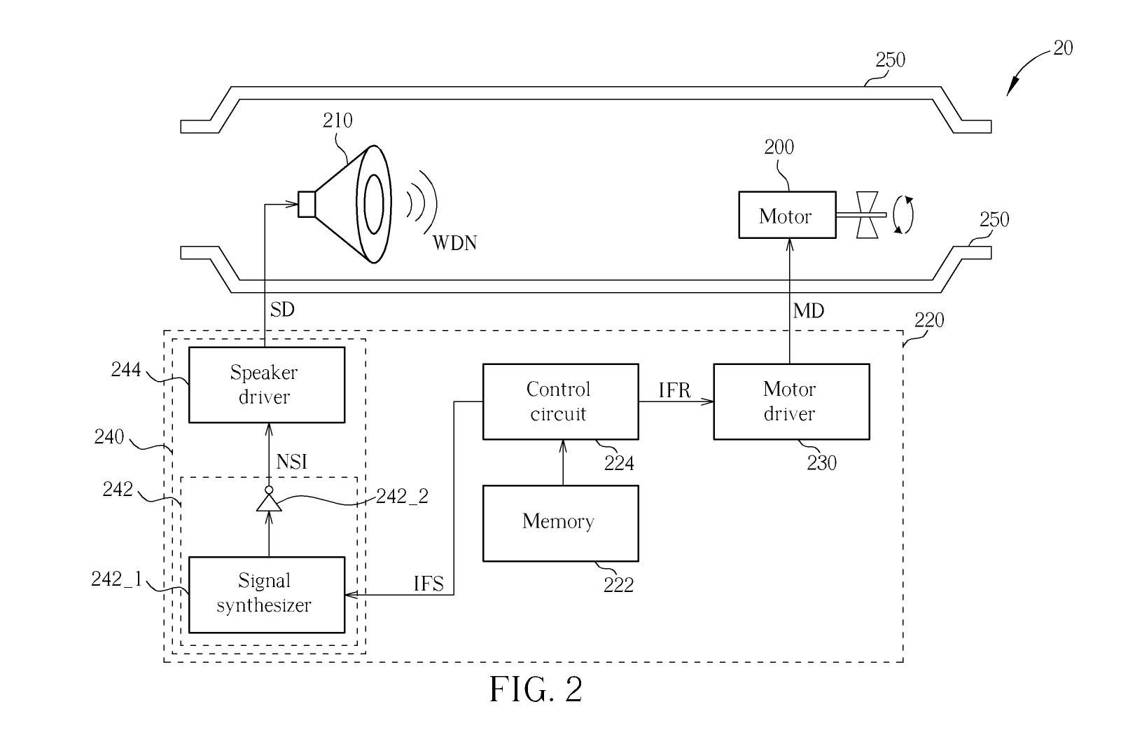

Please refer to FIG. 2, which is a schematic diagram of a motor apparatus 20 according to the embodiment of the present invention. The motor apparatus 20 includes a motor 200, a speaker 210 and a driving device 220. The motor 200 rotates according to a motor driving signal MD. The speaker 210 generates a denoise sound wave WDN according to a speaker driving signal SD to offset a noise of the motor 200. The driving device 220 includes a memory 222, a control circuit 224, a motor driver 230 and an active denoise circuit 240. The memory 222 stores a noise characteristic information of the motor 200. The control circuit 224 determines a rotation speed and a rotation angle of the motor 200 to generate a rotation information IFR, and generates a noise simulation information IFS according to the rotation information IFR and the noise characteristic information. The motor driver 230 is generates the motor driving signal MD according to the rotation information IFR. The active denoise circuit 240 includes a synthesizer 242 and a speaker driver 244. The synthesizer 242 generates an inverted noise simulation signal NSI according to the noise simulation information IFS. The speaker driver 244 generates the speaker driving signal SD according to the inverted noise simulation signal NSI.

In short, in order to prevent the problem that the motor noise can not be offset by the inverted sound wave due to the microphone 110 aging, the motor apparatus 20 utilizes the memory 222 to pre-store the noise information when the motor 200 is rotating rather than recording and analyzing the motor noise. Since the control circuit 224 drives and denoises the motor at the same time, once the rotation information IFR is determined, the corresponding noise simulation information IFS is determined as well. As a result, the motor apparatus 20 generates the denoise sound wave WDN for offsetting the noise without analyzing noise signal, which greatly saves the cost of the control circuit and does not need to consider microphone aging.

In order to achieve the best effect of the sound wave offsetting, the motor 200 and the speaker 210 are preferably fixed on a same axis and covered by a cylindrical housing 250 as shown in FIG. 2. In such a situation, except at two openings of the cylindrical housing 250 for an air inlet and an air outlet of the motor, respectively, the denoise sound wave WDN can offset the motor noise without being interfered by an environment noise.

In detail, the noise characteristic information records noise waveforms and noise frequencies of the motor 200 corresponding to different angles and different rotation speeds as the information for reconstructing the motor noise. Correspondingly, the synthesizer 242 includes a signal synthesizer 242_1 and an inverter 242_2. The signal synthesizer 242_1 reconstructs a noise simulation signal NS according to the noise simulation information IFS. The inverter 242_2 inverts the noise simulation signal NS to generate the inverted noise simulation signal NSI. Since sounds are combinations of sinusoidal waves of different frequencies, the noise simulation signal NS and the inverted noise simulation signal NSI are preferably expressed as sinusoidal waves, but are not limited to this.

In addition, the control circuit 224 can be realized by a micro control unit (MCU), a digital signal processor (DSP), a fuzzy control circuit, a neural network circuit etc. Take the neural network as example, a circuit designer can acquire circuit parameters of the control circuit 224 via training simulation, and embed the circuit parameters into the control circuit 224. As a result, once the angle and the rotation speed of the motor 200 are determined, the control circuit 224 can generate the corresponding rotation information IFR and the noise simulation information IFS.

Noticeably, the motor 200 is not limited to any specific motor, and the present invention can be applied in a direct current brushless motor, a two-phase brushless motor or a conventional DC carbon-brush motor, as long as the memory 222 can store the noise information when the motor is rotating, to generate the required inverted noise simulation signal NSI to offset the motor noise.

In the prior art, as the microphone 110 ages, the denoise functionality of the denoise module 140 weakens and extra noise may be generated. In comparison, the present invention utilizes the memory 222 to store the noise characteristic information of the motor 200, and the control circuit 224 indicates the motor driver 230 to drive the motor 200 and indicates the active denoise circuit 240 to generate the speaker driving signal SD at the same time, so as to drive the speaker 210 to generate the denoise sound wave WDN for offsetting the motor noise. As a result, the motor apparatus 20 does not need to perform complex noise record and noise analyze, which greatly saves the cost of the denoise circuit.

To sum up, the present invention pre-stored the noise information of the motor corresponding to different angles and rotation speeds to drive motor and generate the denoise sound wave for offsetting the motor noise at the same time.

Those skilled in the art will readily observe that numerous modifications and alterations of the device and method may be made while retaining the teachings of the invention.

What is claimed is:

1. A motor apparatus, comprising:
a motor for rotating according to a motor driving signal;
a speaker for generating a denoise sound wave according to a speaker driving signal, to offset a noise of the motor; and
a driving device, comprising:
a memory for storing a noise characteristic information of the motor;
a control circuit for determining a rotation speed and a rotation angle of the motor, to generate a rotation information, and generating a noise simulation information according to the rotation information and the noise characteristic information;
a motor driver for generating the motor driving signal according to the rotation information; and
an active denoise circuit, comprising:
a synthesizer for generating an inverted noise simulation signal according to the noise simulation information; and
a speaker driver for generating the speaker driving signal according to the inverted noise simulation signal.

2. The motor apparatus of claim 1, wherein the motor and the speaker are fixed on a same axis.

3. The motor apparatus of claim 2 further comprising a cylindrical housing for covering the motor and the speaker according to the axis.

4. The motor apparatus of claim 1, wherein the noise characteristic information comprises noise waveforms and noise frequencies of the motor corresponding to different angles and different rotation speeds.

5. The motor apparatus of claim 1, wherein the synthesizer comprises:
a signal synthesizer for reconstructing a noise simulation signal according to the noise simulation information; and
an inverter for inverting the noise simulation signal, to generate the inverted noise simulation signal.

6. The motor apparatus of claim 5, wherein the noise simulation signal and the inverted noise simulation signal are sinusoidal waves.

7. The motor apparatus of claim 1, wherein the control circuit is a microcontroller, a digital signal processor, a fuzzy control circuit or a neural network circuit.

8. The motor apparatus of claim 1, wherein the motor is a direct current (DC) brushless motor.

9. A denoise driving device for driving a motor and offsetting a noise of the motor, the denoise driving device comprises:
a speaker for generating a denoise sound wave according to a speaker driving signal, to offset the noise of the motor; and
a driving device, comprising:
a memory for storing a noise characteristic information of the motor;
a control circuit for determining a rotation speed and a rotation angle of the motor, to generate a rotation information, and generating a noise simulation information according to the rotation information and the noise characteristic information;
a motor driver for generating a motor driving signal according to the rotation information, to drive the motor; and
an active denoise circuit, comprising:
a synthesizer for generating an inverted noise simulation signal according to the noise simulation information; and
a speaker driver for generating the speaker driving signal according to the inverted noise simulation signal.

10. The denoise driving device of claim 9, wherein the motor and the speaker are fixed on a same axis.

11. The denoise driving device of claim 10 further comprising a cylindrical housing for covering the motor and the speaker according to the axis.

12. The denoise driving device of claim 9, wherein the noise characteristic information comprises noise waveforms and noise frequencies of the motor corresponding to different angles and different rotation speeds.

13. The denoise driving device of claim 9, wherein the synthesizer comprises:
a signal synthesizer for reconstructing a noise simulation signal according to the noise simulation information; and
an inverter for inverting the noise simulation signal, to generate the inverted noise simulation signal.

14. The denoise driving device of claim 13, wherein the noise simulation signal and the inverted noise simulation signal are sinusoidal waves.

15. The denoise driving device of claim 9, wherein the control circuit is a microcontroller, a digital signal processor, a fuzzy control circuit or a neural network circuit.

16. The denoise driving device of claim 9, wherein the motor is a direct current (DC) brushless motor.

17. A driving device for driving a motor and a speaker, wherein the speaker is utilized for generating a denoise sound wave according to a speaker driving signal to offset a noise of the motor, the driving device comprising:
a memory for storing a noise characteristic information of the motor;
a control circuit for determining a rotation speed and a rotation angle of the motor, to generate a rotation information, and generate a noise simulation information according to the rotation information and the noise characteristic information;
a motor driver for generating a motor driving signal according to the rotation information, to drive the motor; and
an active denoise circuit, comprising:
a synthesizer for generating an inverted noise simulation signal according to the noise simulation information; and
a speaker driver for generating the speaker driving signal according to the inverted noise simulation signal.

18. The driving device of claim 17, wherein the motor and the speaker are fixed on a same axis.

19. The driving device of claim 18, wherein the motor and the speaker are covered by a cylindrical housing according to the axis.

20. The driving device of claim 17, wherein the noise characteristic information comprises noise waveforms and noise frequencies of the motor corresponding to different angles and different rotation speeds.

21. The driving device of claim 17, wherein the synthesizer comprises:
a signal synthesizer for reconstructing a noise simulation signal according to the noise simulation information; and
an inverter for inverting the noise simulation signal, to generate the inverted noise simulation signal.

22. The driving device of claim 21, wherein the noise simulation signal and the inverted noise simulation signal are sinusoidal waves.

23. The driving device of claim 17, wherein the control circuit is a microcontroller, a digital signal processor, a fuzzy control circuit or a neural network circuit.

24. The driving device of claim 17, wherein the motor is a direct current (DC) brushless motor.
